(19) United States
(12) Patent Application Publication
(10) Pub. No.: US 2025/0172953 A1
(43) Pub. Date: May 29, 2025

(54) Article Transport Facility

(71) Applicant: Daifuku Co., Ltd., Osaka-shi (JP)

(72) Inventor: Yoshitaka Tanaka, Hinocho (JP)

(21) Appl. No.: 18/961,889

(22) Filed: Nov. 27, 2024

(30) Foreign Application Priority Data
Nov. 29, 2023 (JP) 2023-201484

(51) Int. Cl. G05D 1/692; G05D 105/28

(52) U.S. Cl. CPC G05D 1/692; G05D 2105/28

(57) ABSTRACT

In a sequencing process, a control device included in an article transport facility determines the order of passage according to waiting time indices that are determined based on waiting times of a plurality of passage target vehicles at a merging area. The waiting time indices are each determined by correcting the waiting time using a correction coefficient determined based on the status of each of the plurality of passage target vehicles.

### CROSS-REFERENCE TO RELATED APPLICATION

This application claims priority to Japanese Patent Application No. 2023-201484 filed Nov. 29, 2023, the disclosure of which is hereby incorporated by reference in its entirety.

### BACKGROUND OF THE INVENTION

### 1. Field of the Invention

The present invention relates to an article transport facility that includes a plurality of transport vehicles that travel along a predetermined route and a control device that controls the transport vehicles.

### 2. Description of Related Art

An example of such an article transport facility is disclosed as a transport carriage system in JP 2006-313463A. In the following description of the related art, the symbols shown in parentheses are those used in JP 2006-313463A.

In the system disclosed in JP 2006-313463A, lock points are provided at merging areas where portions of a travel route of transport vehicles (5) merge, zones each including a lock point are set (hereinafter, called “controlled zones”), and whether or not a transport vehicle (5) is permitted to pass at a lock point is determined for a zone as a whole.

Before a transport vehicle (5) enters a controlled zone in which a lock point is provided, the transport vehicle (5) issues, to a zone controller (11), a blocking request for prohibiting other transport vehicles (5) from entering the controlled zone. If the zone controller (11) permits the transport vehicle (5) that issued the blocking request to pass through the controlled zone, blocking permission is given, and other transport vehicles (5) are prohibited from passing. After the transport vehicle (5) passes, the zone controller (11) cancels the blocking in the controlled zone so as to enable accepting other transport vehicles (5).

The technology disclosed in JP 2006-313463A involves processing such as setting a controlled zone and monitoring entry or exit of a transport vehicle (5) to or from the controlled zone, often leading to a complex control configuration. In addition, in order to achieve efficient operation of the entire facility, it is desirable that the priority for allowing transport vehicles (5) to pass through the merging area is determined not only based on the timing of entry of the transport vehicles (5) to the controlled zone but also by taking the situation of each transport vehicle (5) into account.

### SUMMARY OF THE INVENTION

In view of the aforementioned circumstances, there is a demand for developing technology that can perform control of a plurality of transport vehicles related to a merging area in a simple and appropriate manner.

The technology for addressing the aforementioned issues is as follows.

An article transport facility including:
a plurality of transport vehicles configured to travel along a predetermined route; and
a control device configured to control the transport vehicles,
the control device being configured to execute merging control for controlling operations of a plurality of the transport vehicles in a merging area where a plurality portions of the route merge,
the merging control including a sequencing process of determining an order of passage in which a plurality of passage target vehicles pass through the merging area, the plurality of passage target vehicles being a plurality of the transport vehicles that are going to pass through the merging area concurrently are referred to as passage target vehicles,
in the sequencing process, the control device being configured to determine the order of passage according to waiting time indices for the plurality of passage target vehicles that are determined based on waiting times of the plurality of passage target vehicles at the merging area, and
the waiting time indices each being determined by correcting the waiting time using a correction coefficient determined based on a status of each of the plurality of passage target vehicles.

According to this configuration, whether or not a passage target vehicle is permitted to pass through the merging area is determined based on the waiting times of passage target vehicles at the merging area. This enables a simple control configuration. Furthermore, the waiting time indices, based on which it is determined whether or not passage is permitted, are determined by correcting actual waiting times using correction coefficients determined according to the statuses of passage target vehicles, respectively. Therefore, it is determined whether or not passage is permitted by taking the statuses of the passage target vehicles into account, and this can be realized by through simple processing of correcting the waiting times using the correction coefficients. As described above, this configuration makes it possible to perform control of a plurality of transport vehicles related to a merging area in a simple and appropriate manner.

Further features and advantages of the technology according to the present disclosure will become clearer from the following description of illustrative and non-limiting embodiments given with reference to the drawings.

### BRIEF DESCRIPTION OF THE DRAWINGS

FIG. 1 is a plan view of an article transport facility.

FIG. 2 is a control block diagram.

FIG. 3 is a diagram illustrating an example of merging control.

FIG. 4 is a diagram illustrating waiting time correction.

FIG. 5 is a diagram illustrating a comparison between waiting time indices.

FIG. 6 is a diagram illustrating an example in which a charging station is provided before a merging area.

FIG. 7 is a diagram illustrating the waiting time correction according to another embodiment.

### DESCRIPTION OF THE INVENTION

Hereinafter, embodiments of an article transport facility will be described with reference to the drawings.

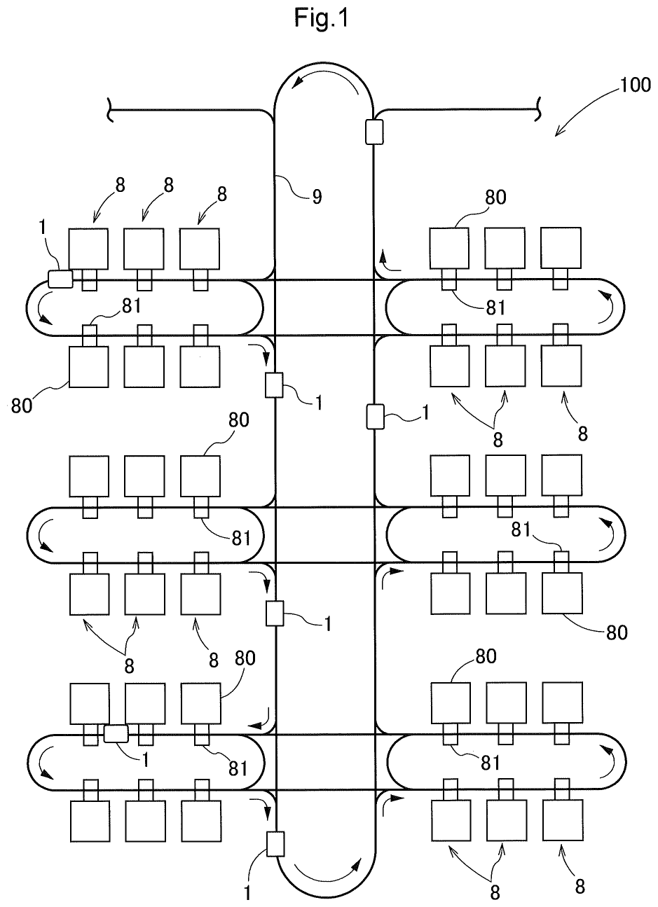

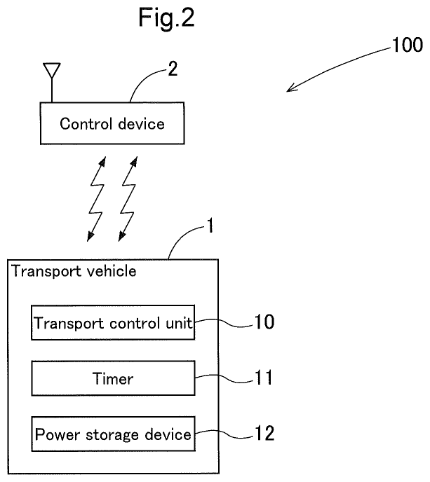

As shown in FIG. 1, an article transport facility 100 includes a plurality of transport vehicles 1 that travel along a predetermined route 9 and a control device 2 (see FIG. 2) that controls the transport vehicles 1.

In the present embodiment, the route 9 is set at a position above a floor surface. For example, the route 9 is configured using a rail near a ceiling. The transport vehicles 1 are configured as so-called overhead transport vehicles and travel on the rail along the route 9.

A plurality of transfer target locations 8 are provided along the route 9. The transfer target locations 8 are below the route 9. The transport vehicles 1 are configured to transfer articles (not shown) to and from the transfer target locations 8 by lifting and lowering the articles.

Each of the plurality of transport vehicles 1 is configured to receive a transport command from a higher-level control device (not shown) that performs overall management of the facility, and execute a task according to the transport command. For example, the transport command includes information on a transport source and a transport destination of an article. Upon receiving the transport command, the transport vehicle 1 transports the article from the transport source to the transport destination. Transport sources and transport include the aforementioned transfer target locations 8.

Various types of articles are handled in the article transport facility 100. In the present example, the article transport facility 100 is used in a semiconductor manufacturing factory. Accordingly, the article is a substrate storage container (a so-called FOUP: Front Opening Unified Pod) that stores substrates (wafers, panels, etc.), a reticle storage container (a so-called reticle pod) that stores reticles, or the like. In this case, the transport vehicles 1 transport articles such as substrate storage containers or reticle storage containers along the route 9 between processes.

In the present embodiment, each transfer target location 8 includes a processing device 80 that performs processing on articles and a placement platform 81 adjacent to the processing device 80. The term “processing on articles” means processing performed on stored objects (substrates or reticles) that are stored in articles serving as storage containers. The transport vehicles 1 receive articles that have been processed by the processing device 80 from the placement platform 81, or deliver articles that have not yet been processed by the processing device 80 to the placement platform 81. The processing device 80 performs various types of processing, such as thin film formation, photolithography, and etching, for example.

As shown in FIG. 2, the control device 2 can communicate with the transport vehicles 1. The control device 2 includes a processor such as a microcomputer and peripheral circuits such as a memory, for example. Various types of processing and functions are realized by cooperation between such hardware and programs executed on the processor of a computer or the like.

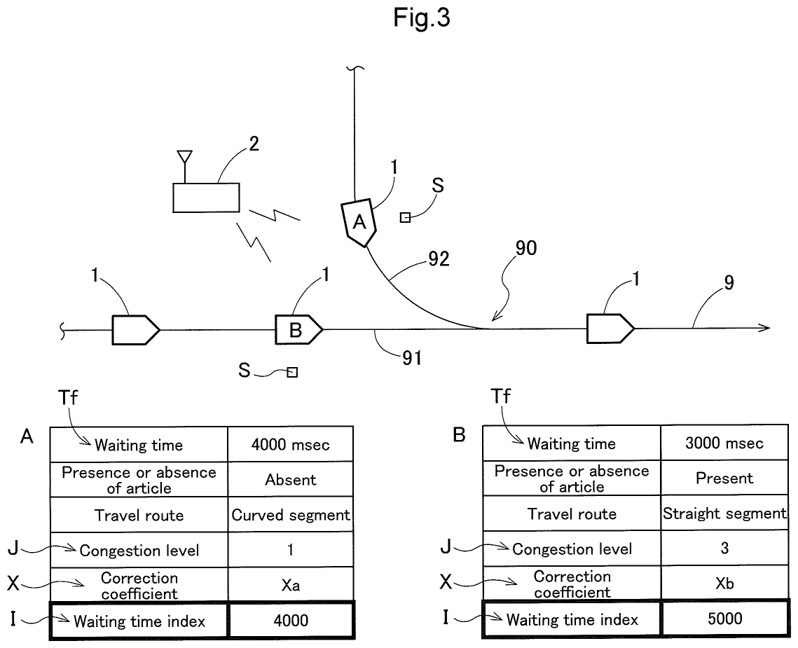

The control device 2 and each transport vehicle 1 are configured to send and receive signals to and from each other. When the transport vehicle 1 is going to pass through a merging area 90 (see FIG. 3) where a plurality of portions of the route 9 merge, the transport vehicle 1 issues a request for permission to pass through the merging area 90 to the control device 2. Then, the control device 2, when permitting the transport vehicle 1 to pass through the merging area 90, issues passage permission to that transport vehicle 1. The request for passage permission is sent and received as a passage request signal. The passage permission is sent and received as a passage permission signal.

In the present embodiment, the transport vehicle 1 includes a transport control unit 10 and a timer 11. In the present embodiment, the transport vehicle 1 further includes a power storage device 12. The transport vehicle 1 can perform various operations, such as traveling and transfer operations, using the electric power stored in the power storage device 12. All the transport vehicles 1 in the article transport facility 100 may include power storage devices 12, or only some of the transport vehicles 1 may include power storage devices 12. That is to say, some or all of the plurality of transport vehicles 1 are each equipped with a power storage device 12 that stores electric power.

The transport control unit 10 is a device including a central processing unit as its core and is configured to control the operation of the transport vehicle 1. The transport control unit 10 also sends and receives signals to and from the control device 2. The timer 11 is configured to measure the elapsed time from any point in time. In the present embodiment, the timer 11 measures the elapsed time from the point in time at which the transport vehicle 1 issues a request for passage permission. However, the time point at which the timer 11 starts measurement may be set as appropriate.

FIG. 3 illustrates a state in which a plurality of transport vehicles 1 are going to pass through the merging area 90, where a plurality of portions of the route 9 merge. In the illustrated example, two portions of the route 9 merge to form the merging area 90. One of the two portions of the route 9 is a straight segment 91 that merges linearly into the merging area 90, and the other is a curved segment 92 that merges in a curved manner into the merging area 90. Whether a portion of the route 9 is a straight segment 91 or a curved segment 92 is relatively determined based on the relationship between the plurality portions of the route 9 that merge into a specific merging area 90. In other words, of two portions of the route 9 that merge, the one with the larger curvature is regarded as a curved segment 92, and the other is regarded as a straight segment 91. This means that there are cases where a straight segment 91 is curved.

The control device 2 is configured to execute merging control for controlling the operations of a plurality of transport vehicles 1 in a merging area 90 where a plurality portions of the route 9 merge.

Here, the plurality of transport vehicles 1 that are going to pass through the merging area 90 concurrently are referred to as passage target vehicles 1. The phrase “passing through concurrently” means passing through the merging area 90 within a predetermined set period of time. This set period of time may be 3000 msec to 5000 msec, for example. When a time determined based on the travel speed and the distance from the current position to the merging area 90 for each of the plurality of transport vehicles 1 is within the set period of time, the plurality of transport vehicles 1 are defined as passage target vehicles 1. In the illustrated example, a transport vehicle 1 indicated by “A” and a transport vehicle 1 indicated by “B” are shown as passage target vehicles 1. Hereinafter, these two passage target vehicles 1 may also be referred to as the “passage target vehicle A” and the “passage target vehicle B”, respectively.

The merging control includes a sequencing process of determining the order of passage in which the plurality of passage target vehicles 1 pass through the merging area 90. In the sequencing process, whether or not the passage of a passage target vehicle 1 is permitted is determined based on waiting time indices I calculated for the plurality of passage target vehicles 1.

In the present embodiment, each passage target vehicle 1 notifies the control device 2 of its own waiting time index I. Then, in the sequencing process, the control device 2 compares the waiting time indices I of the plurality of passage target vehicles 1 and issues passage permission to the passage target vehicle 1 with the higher waiting time index I to pass through the merging area 90.

The waiting time indices I are each determined by correcting the waiting time Tf using a correction coefficient X determined based on the status of each of the plurality of passage target vehicles 1. In the present embodiment, each waiting time index I is corrected so that the larger the correction coefficient X, the higher the value of the waiting time index I. In this example, the waiting time index I is determined by adding the correction coefficient X to the waiting time Tf.

In the present embodiment, the correction coefficient X is set so that when a passage target vehicle 1 is transporting an article, its waiting time index I is higher than when that passage target vehicle 1 is not transporting an article. In this example, the correction coefficient X is set to be larger when the passage target vehicle 1 is transporting an article. A transport vehicle 1 that is transporting an article is executing a task, and arrival of this transport vehicle 1 at its destination may be urgent. On the other hand, the level of urgency for a transport vehicle 1 that is not transporting an article tends to be relatively low because the destination of such a transport vehicle 1 may not yet be fixed. According to the above-described configuration, the correction coefficient X is set to be larger for a passage target vehicle 1 that is transporting an article, and therefore, it is easy to allow this passage target vehicle 1 to pass through the merging area 90 preferentially over a passage target vehicle 1 that is not transporting an article.

In the illustrated example, the passage target vehicle A is not transporting an article (presence or absence of article: “absent”). On the other hand, the passage target vehicle B is transporting an article (presence or absence of article: “present”). Therefore, when the presence or absence of an article is focused on, a correction coefficient Xb for the passage target vehicle B contains a factor that makes it larger than a correction coefficient Xa for the passage target vehicle A.

In the present embodiment, the correction coefficient X is set so that when a passage target vehicle 1 is located on the straight segment 91 that merges linearly into the merging area 90, the waiting time index I is higher than when this passage target vehicle 1 is located on the curved segment 92 that merges in a curved manner into the merging area 90. In this example, the correction coefficient X is set to be larger when the passage target vehicle 1 is located on the straight segment 91. A passage target vehicle 1 traveling on the straight segment 91 tends to travel at a higher travel speed than a passage target vehicle 1 traveling on the curved segment 92. The entire facility can be operated efficiently by allowing such a passage target vehicle 1 that tends to travel at a relatively high travel speed to pass through the merging area 90 preferentially.

In the illustrated example, the passage target vehicle A is located on the curved segment 92 (travel route: curved segment). The passage target vehicle B is located on the straight segment 91 (travel route: straight segment). Therefore, when the route 9 on which the passage target vehicles 1 travel are focused on, the correction coefficient Xb for the passage target vehicle B contains a factor that makes it larger than the correction coefficient Xa for the passage target vehicle A.

In the present embodiment, the correction coefficient X is set so that the higher a congestion level J on a portion of the route 9 where a passage target vehicle 1 is located, the higher the waiting time index I. In this example, the correction coefficient X is set to be larger as the congestion level J increases. Thus, it is easy to allow a passage target vehicle 1 that is located on a portion of the route 9 with a relatively high congestion level J to pass through the merging area 90 preferentially over a passage target vehicle 1 that is located on a portion of the route 9 with a relatively low congestion level J. Therefore, passage target vehicles 1 can travel smoothly on portions of the route 9 with relatively high congestion levels J, and hence, the congestion level J can be made uniform over the entire route 9. The “congestion level J” is determined based on the number of transport vehicles 1 in a predetermined region of the route 9. When a single transport vehicle 1 is focused on, the congestion level J may be determined based on the time for which the transport vehicle 1 is stopped, the travel speed, the time taken to pass through a set specific zone, or the like. Preferably, the “congestion level J” is determined quantitatively through quantification. For example, the congestion level J may be determined using five numerical values on a scale of 1 to 5.

In the illustrated example, on the portion of the route 9 where the passage target vehicle A is located, only the passage target vehicle A is present and the congestion level J is “1” (congestion level: 1). On the portion of the route 9 where the passage target vehicle B is located, a plurality of passage target vehicles 1 are present, and the congestion level J is “3” (congestion level: 3). Accordingly, when the congestion level J is focused on, the correction coefficient Xa for the passage target vehicle A is not affected by the congestion level J. The correction coefficient Xb for the passage target vehicle B is affected by the congestion level J, and the correction coefficient Xb contains a factor that increases the correction coefficient Xb.

As described above, correction coefficients X are determined taking various indicators into account, and, for each of the plurality of passage target vehicles 1, a waiting time index I is determined by adding the correction coefficient X to the waiting time Tf.

In the illustrated example, the correction coefficient Xa for the passage target vehicle A is not affected by the various indicators, namely, the presence or absence of an article, the travel route, and the congestion level J, and is set to “0”. Therefore, the waiting time index I for the passage target vehicle A is calculated by adding the correction coefficient Xa, “0”, to “4000 msec”, which is the waiting time Tf of the passage target vehicle A, and is thus determined to be “4000”. The correction coefficient Xb for the passage target vehicle B is affected by all of the indicators, namely, the presence or absence of an article, the travel route, and the congestion level J, and is set to “2000”. Therefore, the waiting time index I for the passage target vehicle B is calculated by adding the correction coefficient Xb, “2000”, to “3000 msec”, which is the waiting time Tf of the passage target vehicle B, and is thus determined to be “5000”. In this example, a waiting time index I is a dimensionless value without a unit. However, in this example, the waiting time index I is calculated by adding the correction coefficient X to the waiting time Tf, and for this reason, “msec”, which is the same unit as that of the waiting time Tf, may be used as the unit of the waiting time index I. Alternatively, a unit other than “msec” may be used as the unit of the waiting time index I.

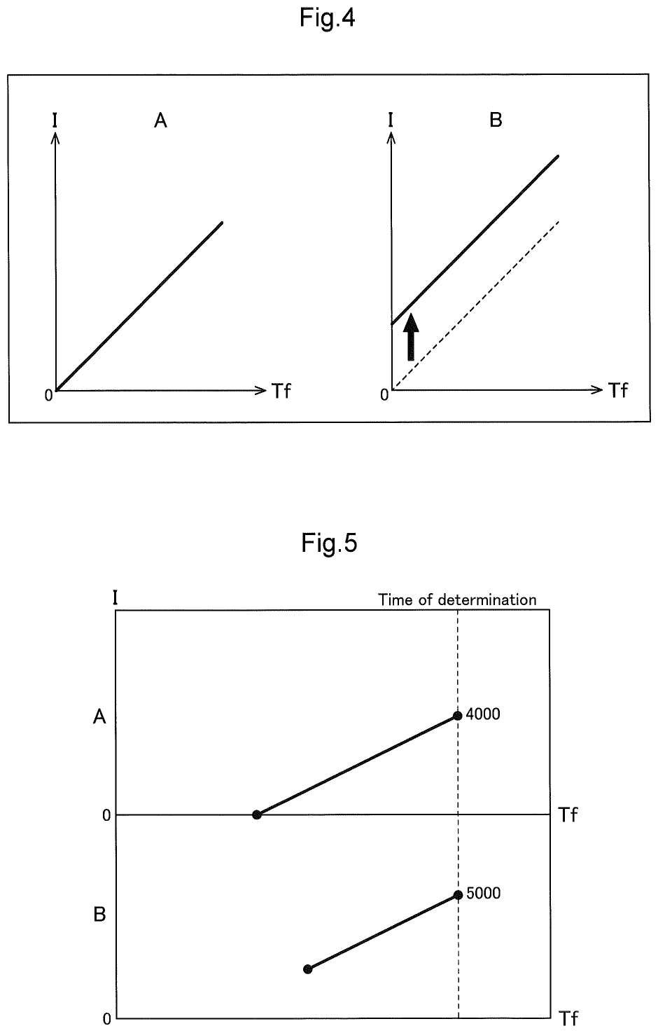

FIG. 4 shows graphs in which the horizontal axis represents the waiting time Tf and the vertical axis represents the waiting time index I. After a passage target vehicle 1 stops at a stop point S, the waiting time Tf and the waiting time index I begin to increase gradually. These are measured by the timer 11 installed in each passage target vehicle 1.

As described above, in this example, the correction coefficient Xa for the passage target vehicle A is “0”, and therefore, the graph is not affected by the addition of the correction coefficient Xa to the waiting time Tf. On the other hand, the correction coefficient Xb for the passage target vehicle B is a positive value (“2000” in this example), and therefore, the graph is shifted upward by the addition of the correction coefficient Xb to the waiting time Tf.

FIG. 5 is a timing diagram from the viewpoint of the control device 2 that executes the sequencing process. In the illustrated example, the passage target vehicle A stops at the stop point S earlier than the passage target vehicle B, and from this point in time, the counting of the waiting time Tf (waiting time index I) starts. For the passage target vehicle B, which stops at the stop point S later than the passage target vehicle A, the counting of the waiting time Tf (waiting time index I) starts at a later point in time than that of the passage target vehicle A.

However, since the correction coefficient Xb for the passage target vehicle B is affected by the various indicators and is thus set to a large value, at the time of determination at which the control device 2, which is executing the sequencing process, determines whether or not to permit passage of the passage target vehicles 1, the waiting time index I (5000) for the passage target vehicle B is higher than the waiting time index I (4000) for the passage target vehicle A. Therefore, as a result of the comparison between the waiting time indices I for the two vehicles, the control device 2 issues passage permission to pass through the merging area 90 to the passage target vehicle B.

In this manner, in the sequencing process, the control device 2 compares waiting time indices I for a plurality of passage target vehicles 1, which are determined based on the waiting times Tf of those vehicles at the merging area 90, and allows the passage target vehicle 1 with the highest waiting time index I to pass before the other passage target vehicles 1.

Here, as described above, in the present embodiment, each transport vehicle 1 includes a power storage device 12 (see FIG. 2). The power storage device 12 is, for example, a battery, a capacitor, or the like.

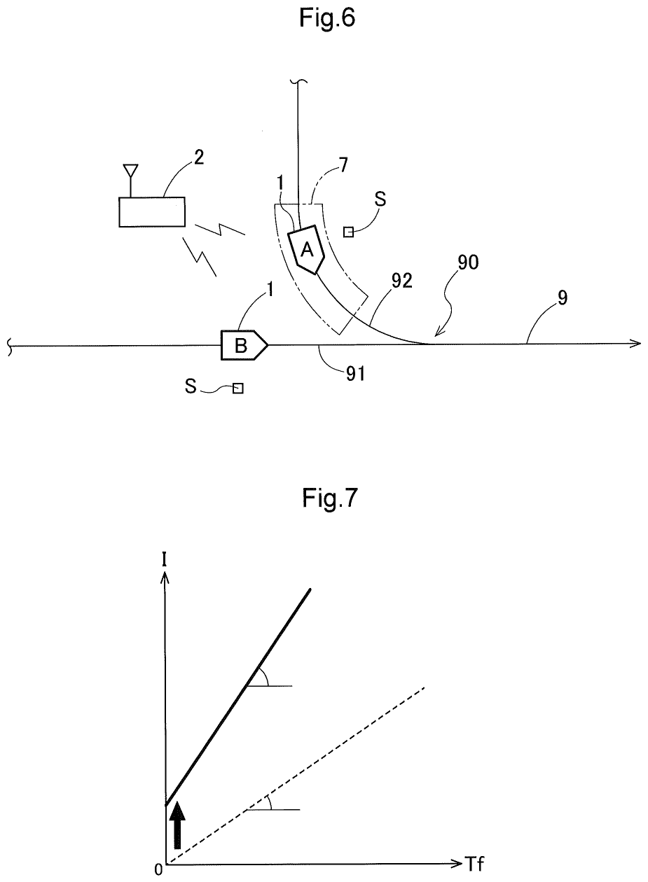

FIG. 6 shows a specific merging area 90 out of a plurality of merging areas 90 in the article transport facility 100.

As shown in FIG. 6, in the present embodiment, a charging station 7 for charging the power storage devices 12 is provided before the merging area 90. For example, a feeder line for performing wireless power transfer is provided along a part of the route 9, and the area of that part where the feeder line is provided is used as the charging station 7. In the present embodiment, the charging station 7 is provided on a curved segment 92, out of a straight segment 91 and the curved segment 92 that merge in the merging area 90.

In the present embodiment, the correction coefficient X is set so that when the amount of electric power stored in the power storage device 12 included in a passage target vehicle 1 is less than or equal to a predetermined reference remaining amount, the waiting time index I is lower than when the amount of electric power stored in the power storage device 12 is more than the reference remaining amount. In this example, the correction coefficient X is set to be smaller when the amount of electric power stored in the power storage device 12 is less than or equal to the reference remaining amount. Thus, the waiting time index I tends to be a relatively low value. Therefore, the passage target vehicle 1 equipped with the power storage device 12 in which the amount of electric power has decreased to an amount less than or equal to the reference remaining amount has a higher likelihood of waiting before the merging area 90. This allows the passage target vehicle 1 to use the waiting time Tf to charge the power storage device 12 at the charging station 7.

In addition, as described above, on the curved segment 92, where the passage target vehicle 1 tends to travel at a relatively low travel speed, the correction coefficient X is inevitably relatively small, which increases the likelihood of the passage target vehicle 1 on the curved segment 92 waiting before the merging area 90. In the present embodiment, since the charging station 7 is provided on the curved segment 92, a situation where it is easy for the passage target vehicle 1 to perform charging can be created.

In the present embodiment, the correction coefficient X is set so that when the amount of electric power stored in the power storage device 12 included in the passage target vehicle 1 is less than or equal to the reference remaining amount, and the charging station 7 is not provided before the merging area 90 that the passage target vehicle 1 is going to pass through, the waiting time index I is higher than when the amount of electric power stored in the power storage device 12 is more than the reference remaining amount. In this example, the correction coefficient X is set to be larger in the former situation. In this case, the waiting time index I tends to be a relatively high value as a result of the correction coefficient X being set to a large value. Therefore, the passage target vehicle 1 equipped with the power storage device 12 in which the amount of electric power has decreased to an amount less than or equal to the reference remaining amount can more easily pass through the merging area 90 without a charging station 7 and can easily perform charging at another charging station 7 or the like earlier.

In the illustrated example, the passage target vehicle B that is located on the straight segment 91 has a higher likelihood of passing through the merging area 90 preferentially. When the passage target vehicle B can pass through the merging area 90 preferentially over the passage target vehicle A, the passage target vehicle B can travel toward a charging station 7 at another location earlier, where charging can be performed.

### Other Embodiments

Next, other embodiments will be described.
(1) In the above embodiment, an example is described in which the waiting time index I is determined by adding the correction coefficient X to the waiting time Tf. However, the present disclosure is not limited to this example, and the waiting time index I may be determined by multiplying the waiting time Tf by the correction coefficient X and adding the correction coefficient X to the waiting time Tf. In this case, as shown in FIG. 7, for example, the slope of the graph is changed by the multiplication, and the graph is shifted upward by the addition. However, the waiting time index I may be determined simply through multiplication by the correction coefficient X. In addition to the aforementioned methods, the waiting time index I may alternatively be determined by subtracting the correction coefficient X from the waiting time Tf or dividing the waiting time Tf by the correction coefficient X. Even in this case, the waiting time index I is set so as to become a higher value through calculation using the correction coefficient X. That is to say, although there are various methods to calculate the waiting time index I using the correction coefficient X, the correction coefficient X is set according to various situations so that the waiting time index I becomes a higher value as a result of the calculation. For example, there also are cases where the smaller the correction coefficient X, the higher the waiting time index I.
(2) In the above embodiment, an example is described in which the correction coefficient X is set so as to be larger for a passage target vehicle 1 that is transporting an article than for a passage target vehicle 1 that is not transporting an article. However, the present disclosure is not limited to this example, and even when all of the plurality of passage target vehicles 1 that can pass through the merging area 90 concurrently are transporting articles, the priority of passage with respect to two passage target vehicles 1 that are transporting articles may be determined by setting the correction coefficients X taking into account at least one of the contents of the articles being transported, the contents of the transport commands received, and the transport destinations of the articles. In other words, the priority of article transport may be reflected in the correction coefficients X.
(3) In the above embodiment, an example is described in which the determination of the correction coefficient X is affected by various situations, such as whether or not the passage target vehicle 1 is transporting an article, the portion of the route 9 where the passage target vehicle 1 is located (i.e., whether that portion is a straight segment 91 or a curved segment 92), and the congestion level J. However, the present disclosure is not limited to this example, and the correction coefficient X may be set for each of the aforementioned situations (this means that a plurality of correction coefficients X are set). In this case, the waiting time index I is determined by correcting the waiting time Tf through calculations using all of the plurality of correction coefficients X.
(4) In the above embodiment, an example is described in which the correction coefficient X is set so that when the passage target vehicle 1 is located on a straight segment 91, where the travel speed tends to be relatively high, the correction coefficient X is larger than that for a passage target vehicle 1 that is located on a curved segment 92, where the travel speed tends to be relatively low. However, the present disclosure is not limited to this example, and the magnitude of the correction coefficient X may be set based on the travel speed of the passage target vehicle 1, independent of the shape of the route 9. In other words, the correction coefficient X may be set so that the higher the travel speed of the passage target vehicle 1 before the merging area 90, the larger the correction coefficient X, or conversely, the lower the travel speed, the smaller the correction coefficient X.
(5) In the above embodiment, an example is described in which, in the sequencing process, the control device 2 compares waiting time indices I for a plurality of passage target vehicles 1, which are determined based on the waiting times Tf of those vehicles at the merging area 90, and allows the passage target vehicle 1 with the highest waiting time index I to pass before the other passage target vehicles 1. However, the present disclosure is not limited to this example, and the control device 2 can determine the order of passage according to the waiting time indices I in the sequencing process. For example, the control device 2 may correct the waiting times Tf using the correction coefficients X and calculate the inverses of the corrected values as waiting time indices I, and then allow the passage target vehicle 1 with the lowest waiting time index I to pass before the other passage target vehicles 1.
(6) In the above embodiment, an example is described in which the control device 2, when permitting a transport vehicle 1 to pass through the merging area 90, issues passage permission to that transport vehicle 1. The passage permission may be issued to a plurality of transport vehicles 1 collectively. In this case, the control device 2 can specify the orders of passage for the plurality of transport vehicles 1 based on the waiting time indices I for the individual transport vehicles 1, and then issue passage permission to the individual transport vehicles 1. Thus, the transport vehicles 1 can pass through the merging area 90 without interfering with each other.
(7) In the above embodiment, an example is described in which the timer 11 measures the elapsed time from the point in time at which the transport vehicle 1 issues a request for passage permission. However, the present disclosure is not limited to this example, and the timer 11 may measure the elapsed time from the point in time at which the transport vehicle 1 stops at a stop point S set before the merging area 90.
(8) In the above embodiment, an example is described in which the transport vehicle 1 includes the timer 11. However, the present disclosure is not limited to this example, and the control device 2 may include the timer 11. In this case, the timer 11 included in the control device 2 may measure the elapsed time after each transport vehicle 1 stops before the merging area 90.
(9) It should be noted that the configurations disclosed in the above-described embodiments can also be applied in combination with configurations disclosed in other embodiments as long as no contradiction arises. Regarding such other configurations as well, the embodiments disclosed in this specification are merely examples in all respects. Therefore, various modifications can be made as appropriate without departing from the spirit of the present disclosure.

### Overview of Embodiments

The following is an overview of embodiments of the present invention.

An article transport facility includes:
a plurality of transport vehicles configured to travel along a predetermined route; and
a control device configured to control the transport vehicles,
the control device being configured to execute merging control for controlling operations of a plurality of the transport vehicles in a merging area where a plurality of portions of the route merge,
the merging control including a sequencing process of determining an order of passage in which a plurality of passage target vehicles pass through the merging area, the plurality of passage target vehicles being a plurality of the transport vehicles that are going to pass through the merging area concurrently,
in the sequencing process, the control device being configured to determine the order of passage according to waiting time indices for the plurality of passage target vehicles that are determined based on waiting times of the plurality of passage target vehicles at the merging area, and
the waiting time indices each being determined by correcting the waiting time using a correction coefficient determined based on a status of each of the plurality of passage target vehicles.

According to this configuration, whether or not a passage target vehicle is permitted to pass through the merging area is determined based on the waiting times of passage target vehicles at the merging area. This enables a simple control configuration. In addition, the waiting time indices, based on which it is determined whether or not passage is permitted, are determined by correcting actual waiting times using correction coefficients determined according to the statuses of the passage target vehicles. Therefore, it is determined whether or not passage is permitted by taking the statuses of the passage target vehicles into account, and this can be realized through simple processing of correcting the waiting times using the correction coefficients. As described above, this configuration makes it possible to perform control of a plurality of transport vehicles related to a merging area in a simple and appropriate manner.

It is preferable that, in the sequencing process, the control device is configured to compare the waiting time indices for the plurality of passage target vehicles and allow the passage target vehicle with the highest waiting time index to pass before the other passage target vehicles.

According to this configuration, it is possible to correlate an increase or decrease in the waiting time with an increase or decrease in the waiting time index. This makes it easier to perform control of a plurality of transport vehicles related to a merging area in a simple manner.

It is preferable that the correction coefficient is set so that when the passage target vehicle is transporting an article, the waiting time index for the passage target vehicle is higher than when the passage target vehicle is not transporting the article.

According to this configuration, it is easy to allow a passage target vehicle that is transporting an article to pass through the merging area preferentially over a passage target vehicle that is not transporting an article.

It is preferable that the correction coefficient is set so that when the passage target vehicle is located on a straight segment of the route that merges linearly into the merging area, the waiting time index for the passage target vehicle is higher than when the passage target vehicle is located on a curved segment of the route that merges in a curved manner into the merging area.

A passage target vehicle traveling on the straight segment tends to travel at a higher travel speed than a passage target vehicle traveling on the curved segment. The entire facility can be operated efficiently by allowing such a passage target vehicle that tends to travel at a relatively high travel speed to pass through the merging area preferentially. According to this configuration, it is easy to allow a passage target vehicle that is located on a straight segment to pass through the merging area preferentially over a passage target vehicle that is located on a curved segment. Therefore, the entire facility can be efficiently operated more easily.

It is preferable that the correction coefficient is set so that the higher the congestion level on a portion of the route where the passage target vehicle is located, the higher the waiting time index.

According to this configuration, it is easy to allow a passage target vehicle that is located on a portion of the route with a relatively high congestion level to pass through the merging area preferentially over a passage target vehicle that is located on a portion of the route with a relatively low congestion level. Therefore, the congestion level can be made uniform over the entire route, and hence, the entire facility can be efficiently operated more easily.

It is preferable that some or all of the plurality of transport vehicles are each equipped with a power storage device configured to store electric power,
a charging station for charging the power storage device is provided before the merging area, and
the correction coefficient is set so that when the amount of electric power stored in the power storage device included in the passage target vehicle is less than or equal to a predetermined reference remaining amount, the waiting time index is lower than when the amount of electric power stored in the power storage device is more than the reference remaining amount.

According to this configuration, when the amount of electric power stored in the power storage device included in the passage target vehicle is less than or equal to the predetermined reference remaining amount, the correction coefficient is set to be small, and therefore, the waiting time index is unlikely to be a high value. Accordingly, the passage target vehicle is assigned a lower priority and has a higher likelihood of waiting before the merging area. Also, according to this configuration, the passage target vehicle equipped with the power storage device can use the period during which the vehicle waits before the merging area to charge the power storage device.

It is preferable that the correction coefficient is set so that when the amount of electric power stored in the power storage device included in the passage target vehicle is less than or equal to the reference remaining amount, and the charging station is not provided before the merging area that the passage target vehicle is going to pass through, the waiting time index is higher than when the amount of electric power stored in the power storage device is more than the reference remaining amount.

According to this configuration, when the amount of electric power stored in the power storage device is less than or equal to the reference remaining amount, and there is no charging station before the merging area that the passage target vehicle is going to pass through, the correction coefficient is set to be large, and therefore, the waiting time index is likely to be a high value. Therefore, the passage target vehicle with the amount of electric power stored in the power storage device being less than or equal to the reference remaining amount can more easily pass through the merging area and can easily perform charging at another charging station or the like earlier.

### INDUSTRIAL APPLICABILITY

The technology according to present disclosure is applicable to an article transport facility that includes a plurality of transport vehicles that travel along a predetermined route and a control device that controls the transport vehicles.

What is claimed is:

1. An article transport facility comprising:
a plurality of transport vehicles configured to travel along a predetermined route; and
a control device configured to control the transport vehicles, and
wherein:
the control device is configured to execute merging control for controlling operations of a plurality of the transport vehicles in a merging area where a plurality of portions of the route merge,
the merging control comprises a sequencing process of determining an order of passage in which a plurality of passage target vehicles pass through the merging area, the plurality of passage target vehicles comprising a plurality of the transport vehicles that are going to pass through the merging area concurrently,
in the sequencing process, the control device is configured to determine the order of passage according to waiting time indices for the plurality of passage target vehicles that are determined based on waiting times of the plurality of passage target vehicles at the merging area, and
the waiting time indices are each determined by correcting the waiting time using a correction coefficient determined based on a status of each of the plurality of passage target vehicles.

2. The article transport facility according to claim 1,
wherein, in the sequencing process, the control device is configured to compare the waiting time indices for the plurality of passage target vehicles and allow the passage target vehicle with a highest waiting time index to pass through the merging area before the other passage target vehicles.

3. The article transport facility according to claim 2,
wherein the correction coefficient is set so that when the passage target vehicle is transporting an article, the waiting time index for the passage target vehicle is higher than when the passage target vehicle is not transporting the article.

4. The article transport facility according to claim 2,
wherein the correction coefficient is set so that when the passage target vehicle is located on a straight segment of the route that merges linearly into the merging area, the waiting time index for the passage target vehicle is higher than when the passage target vehicle is located on a curved segment of the route that merges in a curved manner into the merging area.

5. The article transport facility according to claim 2,
wherein the correction coefficient is set so that the higher a congestion level on a portion of the route where the passage target vehicle is located, the higher the waiting time index.

6. The article transport facility according to claim 2, wherein:
some or all of the plurality of transport vehicles are each equipped with a power storage device configured to store electric power,
a charging station for charging the power storage device is provided before the merging area, and
the correction coefficient is set so that when an amount of electric power stored in the power storage device included in the passage target vehicle is less than or equal to a predetermined reference remaining amount, the waiting time index is lower than when the amount of electric power stored in the power storage device is more than the reference remaining amount.

7. The article transport facility according to claim 6,
wherein the correction coefficient is set so that when the amount of electric power stored in the power storage device included in the passage target vehicle is less than or equal to the reference remaining amount, and the charging station is not provided before the merging area that the passage target vehicle is going to pass through, the waiting time index is higher than when the amount of electric power stored in the power storage device is more than the reference remaining amount.
